(19) United States
(12) Patent Application Publication
(10) Pub. No.: US 2011/0183069 A1
(43) Pub. Date: Jul. 28, 2011

(54) DEPOSITION APPARATUS, DEPOSITION METHOD, AND STORAGE MEDIUM HAVING PROGRAM STORED THEREIN

(75) Inventors: Hiroyuki Ikuta, Miyagi (JP); Tomohiko Edura, Miyagi (JP); Toyohiro Kamada, Miyagi (JP)

(73) Assignee: TOKYO ELECTRON LIMITED, Tokyo (JP)

(21) Appl. No.: 13/121,587

(22) PCT Filed: Sep. 18, 2009
(86) PCT No.: PCT/JP2009/066332

§ 371 Date: Mar. 30, 2011

(30) Foreign Application Priority Data
Sep. 30, 2008 (JP) 2008-253731

(51) Int. Cl. C23C 16/448; C23C 16/455; C23C 16/52

(52) U.S. Cl. 427/255.23; 118/726; 118/665; 118/697

(57) ABSTRACT

A deposition apparatus includes: a plurality of deposition sources, each of which includes a material container and a carrier gas introducing pipe, vaporizes a film-forming material stored in the material container, and transfers vaporized molecules of the film-forming material by using a first carrier gas introduced from the carrier gas introducing pipe; a connecting pipe, which is connected to the plurality of deposition sources and transfers the vaporized molecules of the film-forming material transferred from each deposition source; a bypass pipe, which is connected to the connecting pipe and directly introduces a second carrier gas to the connecting pipe; and a processing container, which includes a built-in discharge mechanism connected to the connecting pipe and forms a film on a target object therein by discharging, from the discharge mechanism, the vaporized molecules of the film-forming material transferred by using the first and second carrier gases.

### TECHNICAL FIELD

The present invention relates to a deposition apparatus, a deposition method, and a storage medium having a program stored therein, and more particularly, to controlling a deposition rate of a deposition apparatus by adjusting flow of a carrier gas.

### BACKGROUND ART

When electronic device such as a flat panel display is manufactured, a deposition technology is used. In this deposition technology, a film is formed on a target object by vaporizing a predetermined film-forming material and depositing the vaporized film-forming molecules onto the target object. It is very important to precisely control a D/R (Deposition Rate) on the target object when the device is manufactured by using the deposition technology, since performance of a product is increased as a film of good quality is uniformly formed on the target object. Accordingly, in related art, it has been suggested a method of providing a film thickness sensor near a substrate and adjusting a temperature of a deposition source based on results detected by the film thickness sensor in such a way that a deposition rate becomes uniform (for example, refer to Patent Document 1).

(Patent Document 1) Japanese Laid-Open Patent Publication No. 2005-325425

### DISCLOSURE OF THE INVENTION

### Technical Problem

However, following problems occur when different types of film-forming materials are vaporized in a plurality of deposition sources, vaporized molecules of each film-forming material are mixed and transferred to a processing container, and a film forming process is performed on a target object in the processing container. In other words, a film thickness sensor provided near the target object is able to detect a deposition rate of the film-forming materials after being mixed, but cannot detect an evaporation rate of the film-forming material of each deposition source individually.

In this regard, a deposition rate of a material of each deposition source may be detected by inserting a valve in a transfer passage of the film-forming material of each deposition source and closing valves of deposition sources excluding a deposition source to detect an evaporation rate of a material when the evaporation rate of each deposition source is detected. However, when a deposition rate of single film-forming material is detected in a state where the valves of the deposition sources excluding the deposition source to detect the evaporation rate of the material are closed, pressure in a transfer passage that transfers the single material may be decreased lower than pressure in a transfer passage under co-deposition by vapor pressure (partial pressure) in the deposition source for which the valve is closed. Consequently, the detected evaporation rate of the single film-forming material differs from an actual evaporation rate under co-deposition, and thus it is not considered that the actual evaporation rate under co-deposition is measured.

Meanwhile, if the film thickness sensor is disposed on each deposition source, the evaporation rate of the film-forming material of each deposition source can be detected individually. However, in such a method, not only expenses increase since as many film thickness sensors as the number of deposition sources are required, but also burden of control increases in normal situations and during maintenance. Further, physical space is required since as many film thickness sensors as the number of deposition sources are disposed.

To address the above problem, the present invention provides a deposition apparatus, a deposition method, and a storage medium having a program stored therein which precisely control an evaporation rate of each film-forming material stored in each of a plurality of deposition sources and a deposition rate on a target object.

### Technical Solution

In other words, to address the above problem, according to an aspect of the present invention, there is provided a deposition apparatus including: a plurality of deposition sources, each of which includes a material container and a carrier gas introducing pipe, vaporizes a film-forming material stored in the material container, and transfers vaporized molecules of the film-forming material by using a first carrier gas introduced from the carrier gas introducing pipe; a connecting pipe which is connected to each of the plurality of deposition sources and transfers the vaporized molecules of the film-forming material transferred from each deposition source; a bypass pipe which is connected to the connecting pipe and directly introduces a second carrier gas to the connecting pipe; and a processing container which includes a built-in discharge mechanism connected to the connecting pipe and forms a film on a target object therein by discharging, from the discharge mechanism, the vaporized molecules of the film-forming material transferred by using the first and second carrier gases.

Here, vaporization not only includes a phenomenon where liquid changes to gas, but also includes a phenomenon where solid directly changes to gas without passing through a liquid state (i.e., sublimation).

According to above configuration, for example, a deposition rate on a target object is detected based on a signal output from a film thickness sensor, such as QCM (Quartz Crystal Microbalance) disposed near the target object. Here, even when a flow of the first carrier gas introduced from each deposition source is changed, a total flow of the first and second carrier gases can be maintained constant by changing a flow of the second carrier gas introduced from the bypass pipe according to the change of the flow of the first carrier gas.

An evaporation rate (vaporization rate) of a material of each deposition source may be adjusted by the flow of the first carrier gas introduced to each deposition source. As such, since a mixture ratio of film-forming materials contained in the film on the target object may be precisely controlled by adjusting the flow of the first carrier gas, a film of good quality may be formed.

Meanwhile, if the flow of the first carrier gas is changed in order to control the mixture ratio of each film-forming material, pressure inside the connecting pipe transferring the vaporized molecules of the material by using the first carrier gas is changed. However, according to the present invention, as described above, the total flow of the first and second carrier gases can be maintained constant by changing the flow of the second carrier gas introduced from the bypass pipe. As a result, the pressure inside the connecting pipe may be constant. Accordingly, the deposition rate may be maintained constant. In other words, according to the configuration of the present invention, the mixture ratio of the film-forming materials in the film may be accurately controlled by adjusting the flow of the first carrier gas, thereby forming a film having good properties, and at the same time, the pressure inside the transfer passage extended to the discharge mechanism may be maintained constant by adjusting the flow of the second carrier gas, thereby maintaining constant the deposition rate on the target object.

Also, a carrier gas may be an insert gas, such as an argon gas, a helium gas, a krypton gas, a xenon gas, or the like. Also, in the above described deposition apparatus, an organic EL film or an organic metal film may be formed on the target object by depositing an organic EL film-forming material or an organic metal film-forming material as the film-forming material.

The deposition apparatus may further include: a plurality of opening and closing mechanisms, which are each provided between the plurality of deposition sources and the connecting pipe and open or close transfer passages connecting the plurality of deposition sources and the connecting pipe; and a controller, which adjusts a flow of the second carrier gas according to change of a flow of the first carrier gas introduced from the plurality of deposition sources to the connecting pipe due to the opening and closing of the transfer passage by the plurality of opening and closing mechanisms.

The bypass pipe may be connected to the connecting pipe, at a location further from the discharge mechanism than locations where the plurality of deposition sources are connected to the connecting pipe.

The controller may include: a storage unit, which shows a relationship between a deposition rate of each film-forming material and a flow of a carrier gas; a deposition rate calculating unit, which calculates a deposition rate onto the target object based on an output signal from a film thickness sensor disposed inside the processing container; a first carrier gas adjusting unit, which adjusts a flow of the first carrier gas in each deposition source so that the deposition rate calculated by the deposition rate calculating unit is close to a target deposition rate, by using the relationship between the deposition rate and the flow of the carrier gas shown in the storage unit; and a second carrier gas adjusting unit, which adjusts a flow of the second carrier gas according to the change of the flow of the first carrier gas introduced to the connecting pipe according to the adjustment of the first carrier gas adjusting unit.

The first carrier gas adjusting unit may adjust, if a difference between the deposition rate calculated by the deposition rate calculating unit and the target deposition rate of each deposition source is smaller than a predetermined threshold value, the flow of the first carrier gas in each deposition source so that the deposition rate becomes close to the target deposition rate of each deposition source.

The second carrier gas adjusting unit may adjust the flow of the second carrier gas introduced to the bypass pipe so that a total flow of the first and second carrier gases transferred through the connecting pipe does not change.

The deposition apparatus may further include a temperature adjusting unit, which adjusts, if the difference between the deposition rate of each deposition source calculated by the deposition rate calculating unit and the target deposition rate of each deposition source is equal to or higher than the predetermined threshold value, a temperature of each deposition source so that the deposition rate becomes close to the target deposition rate of each deposition source.

Also, to address the above problem, according to another aspect of the present invention, there is provided a deposition method including: vaporizing, in a plurality of deposition sources each including a material container and a carrier gas introducing pipe, each film-forming material stored in the material container, and transferring vaporized molecules of the film-forming material by using a first carrier gas introduced from the carrier gas introducing pipe; transferring the vaporized molecules of the film-forming material transferred from each deposition source, to a connecting pipe connected to each of the plurality of deposition sources; directly introducing a second carrier gas to the connecting pipe from a bypass pipe connected to the connecting pipe; and discharging, from a discharge mechanism connected to the connecting pipe, the vaporized molecules of the film-forming material transferred by using the first and second carrier gases and forming a film on a target object inside a processing container.

The deposition method may further include opening and closing transfer passages connecting the plurality of deposition sources and the connecting pipe, by using a plurality of opening and closing mechanisms respectively provided between the plurality of deposition sources and the connecting pipe, wherein, in the directly introducing of the second carrier gas to the connecting pipe from the bypass pipe, the second carrier gas is introduced to the connecting pipe while adjusting a flow of the second carrier gas according to change of the flow of the first carrier gas introduced to the connecting pipe from the plurality of deposition sources due to opening and closing of the transfer passages by using the opening and closing mechanism.

Also, to address the above problem, according to another aspect of the present invention, there is provided a storage medium having stored therein a computer program for executing: a process of vaporizing, in a plurality of deposition sources each including a material container and a carrier gas introducing pipe, each film-forming material stored in the material container, and transferring vaporized molecules of the film-forming material by using a first carrier gas introduced from the carrier gas introducing pipe; a process of directly introducing a second carrier gas to the connecting pipe from a bypass pipe connected to the connecting pipe; and a process of transferring the vaporized molecules of the film-forming material to a discharge mechanism connected to the connecting pipe by using the first and second carrier gases, and forming a film on a target object inside a processing container by discharging the vaporized molecules of the film-forming material from an discharge mechanism.

### Advantageous Effects

As described above, according to the present invention, an evaporation rate of each film-forming material stored in each of a plurality of deposition source, and a deposition rate on a target object can be precisely controlled.

### BRIEF DESCRIPTION OF THE DRAWINGS

FIG. 1 is a schematic perspective view of a 6-layer continuous film forming system, according to an embodiment of the present invention;

FIG. 2 is a structural diagram of a stacked film obtained according to a 6-layer continuous film forming process, according to the same embodiment;

FIG. 3 is a cross-sectional view taken along a line A-A of FIG. 1;

FIG. 4 is a graph showing an example of a correlation between a temperature of a deposition source unit and a deposition rate;

FIG. 5 is a graph showing an example of a correlation between a flow of a carrier gas and a deposition rate;

FIG. 6 is a functional configuration diagram of a controller according to the same embodiment;

FIG. 7 is a flowchart showing a process of checking an evaporation rate, according to the same embodiment;

FIG. 8 is a flowchart showing a process of controlling a deposition rate, according to the same embodiment;

FIG. 9A is a diagram showing opening and closing of valves and gas flow while checking an evaporation rate, according to the same embodiment;

FIG. 9B is a diagram showing opening and closing of valves and gas flow while checking an evaporation rate, according to the same embodiment;

FIG. 10A is a diagram showing opening and closing of valves and gas flow while checking an evaporation rate when a bypass pipe does not exist;

FIG. 10B is a diagram showing opening and closing of valves and gas flow while checking an evaporation rate when a bypass pipe does not exist;

FIG. 11A is a diagram showing opening and closing of valves and gas flow while controlling a deposition rate, according to the same embodiment;

FIG. 11B is a diagram showing opening and closing of valves and gas flow while controlling a deposition rate, according to the same embodiment;

FIG. 12A is a diagram showing opening and closing of valves and gas flow while controlling a deposition rate when a bypass pipe does not exist;

FIG. 12B is a diagram showing opening and closing of valves and gas flow while controlling a deposition rate when a bypass pipe does not exist; and

FIG. 13 is a graph showing a relationship between each evaporation rate and a deposition rate.

### EXPLANATION ON REFERENCE NUMERALS

10: deposition apparatus
100: deposition source unit
200: connecting pipe
300: valve
310: bypass pipe
400: discharge mechanism
410: QCM
430: temperature controller
440: gas supply source
450a, 450b: mass flow controller
600: deposition mechanism
700: controller
710: storage unit
720: input unit
730: deposition rate calculating unit
740: film thickness control converting unit
750: temperature adjusting unit
760: first carrier gas adjusting unit
770: second carrier gas adjusting unit
780: output unit

### BEST MODE FOR CARRYING OUT THE INVENTION

Hereinafter, the present invention will be described in detail by explaining exemplary embodiments of the invention with reference to the attached drawings. Like reference numerals in the drawings denote like elements, and thus overlapping descriptions will be omitted. Also in the specification, 1 mTorr is (10⁻³×101325/760)Pa and 1 sccm is (10⁻⁶/60)m³/sec.

### Embodiment 1

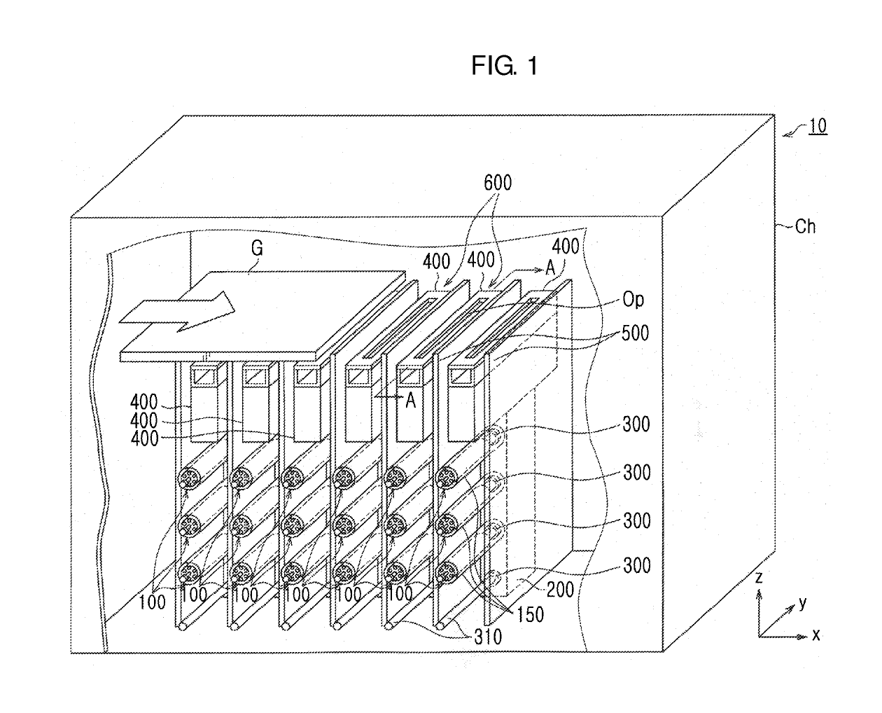

First, a 6-layer continuous film forming system according to an embodiment 1 of the present invention will be described with reference to FIG. 1.

[6-Layer Continuous Film Forming System]

FIG. 1 is a view schematically showing a perspective view of a deposition apparatus is according to the present embodiment. A deposition apparatus 10 is an apparatus capable of continuously forming 6 layers of an organic film. The deposition apparatus 10 is provided inside a processing container Ch having a rectangular shape. The deposition apparatus 10 includes 6×3 deposition source units 100, 6×3 water cooling jackets 150, 6×1 connecting pipes 200, 6×4 valves 300, 6×1 bypass pipe 310, 6×1 discharge mechanisms 400 and 7 partition walls 500 inside the processing container Ch. The inside of the processing container Ch holds a desired vacuum level by using an exhauster that is not shown. Hereinafter, the 3 deposition source units 100, the 3 water cooling jackets 150, the connecting pipe 200, the 4 valves 300, the bypass pipe 310, and the discharge mechanism 400, which are defined by each the partition wall 500, are also referred to as a deposition mechanism 600.

Each deposition source unit 100 is inserted into the water cooling jacket 150 having a cylinder shape without contacting the water cooling jacket 150. The cooling water jacket 150 cools down each deposition source unit 100. The 3 deposition source units 100 included in the deposition mechanism 600 have the same external shapes and internal structures, and each stores therein a film-forming material. The connecting pipes 200 are disposed at regular intervals in parallel with each other in a state where respective one ends of the connecting pipes 200 in a length direction (z-direction) are fixed to a bottom wall of the deposition apparatus 10, and respective other ends of the connecting pipes 200 hold the discharge mechanisms 400. Each connecting pipe 200 is connected to the 3 deposition source units 100 and the bypass pipe 310. The valves 300 are respectively provided at connecting portions between the deposition source units 100 and the connecting pipe 200 and between the bypass pipe 310 and the connecting pipe 200. Accordingly, film forming molecules vaporized in each deposition source unit 100 are discharged from an opening Op formed in an upper center of each discharge mechanism 400 through each connecting pipe 200.

The partition walls 500 are provided to divide into each of deposition mechanism 600, thereby preventing the film forming molecules discharged from the neighboring openings Op from being mixed together. A substrate G moves slightly above each discharge mechanism 400 after being placed on a slidable holding stage that is not shown, and a film forming process is performed on the substrate G by vaporized molecules of the film-forming material discharged from the discharge mechanism 400.

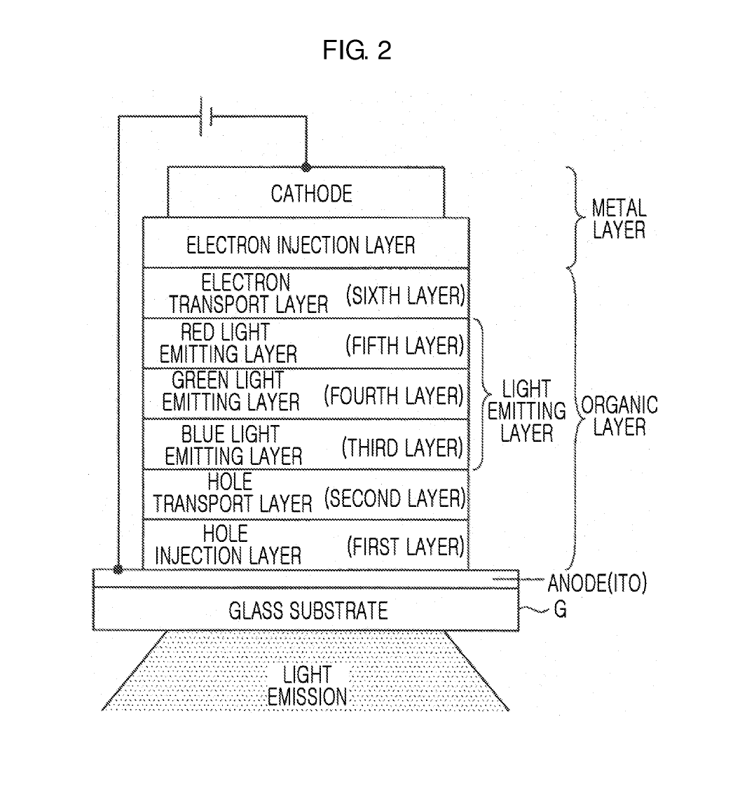

A result of performing a 6-layer continuous film forming process by the deposition apparatus 10 described above is shown in FIG. 2. Here, as the substrate G moves above each discharge mechanism 400 of the deposition apparatus 10 at a certain speed, a hole injection layer of a first layer, a hole transport layer of a second layer, a blue light emitting layer of a third layer, a green light emitting layer of a fourth layer, a red light emitting layer of a fifth layer, and an electron transport layer of a sixth layer are sequentially formed on an ITO of the substrate G. Here, the blue, green, and red light emitting layers of the third through fifth layers are light emitting layers that emit lights via recombination of holes and electrons. Also, a metal layer (electron injection layer and cathode) on an organic layer is formed by sputtering in a sputter device.

[Deposition Mechanism 600]

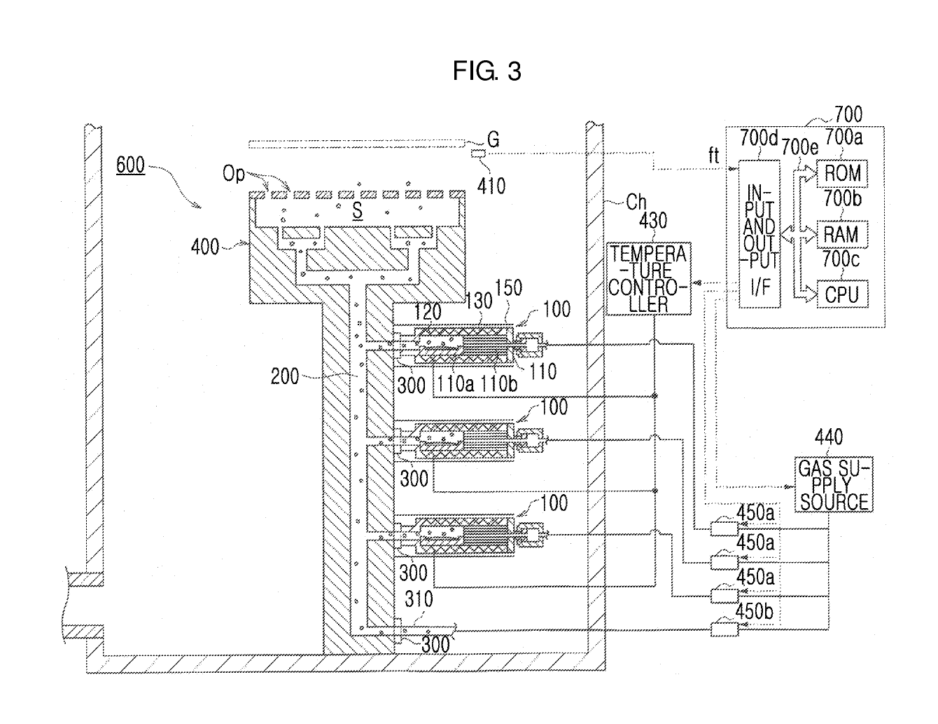

Next, the deposition mechanism 600 and peripheral devices thereof will be described with reference to FIG. 3, which is a cross-sectional view taken along a line A-A of FIG. 1. Each deposition source unit 100 includes a material injecting unit 110 and an external case 120. The external case 120 has a bottle shape, and the material injecting unit 110 is inserted from an opening at a right end of the external case 120. The inside of the external case 120 is sealed by inserting the material injecting unit 110 into the external case 120. During a process, the inside of the external case 120 maintains a predetermined vacuum level.

The material injecting unit 110 includes a material container 110a that stores a film-forming material, and a carrier gas introducing pipe 110b that introduces a carrier gas. An end of each deposition source unit 100 is connected to a gas supply source 440 through a mass flow controller 450a provided at each deposition source unit. A carrier gas (for example, an argon gas) output from the gas supply source 440 is supplied to each deposition source unit 100 while a flow of the carrier gas is adjusted through an opening degree of the mass flow controller 450a. A peripheral portion of the external case 120 is is surrounded by a heater 130. The deposition source unit 100 vaporizes the film-forming material stored in the material container 110a through heating of the heater 130. The vaporized film-forming material is transferred toward the substrate by using the carrier gas introduced from the carrier gas introducing pipe 110b. Here, the deposition source unit 100 is an example of a deposition source, which vaporizes a film-forming material stored in a material container and transfers vaporized molecules of the film-forming material by using a first carrier gas introduced from a carrier gas introducing pipe.

The 3 deposition source units 100 and the bypass pipe 310 are, in parallel with each other, connected to the connecting pipe 200. The valve 300 is provided between each deposition source unit 100 and the connecting pipe 200. The valve 300 is an example of an opening and closing mechanism, which opens or closes a transfer passage connecting the deposition source unit 100 and the connecting pipe 200.

The discharge mechanism 400 is provided at a front end side of the connecting pipe 200. The vaporized molecules of the film-forming material output from each deposition source unit 100 are moved to the connecting pipe 200 by using a first carrier gas, are transferred upward inside the connecting pipe 200 by using the first carrier gas and a second carrier gas, and are discharged from the upper opening Op of the discharge mechanism 400. Accordingly, a desired film is formed on the substrate G inside the processing container Ch. The bypass pipe 310 is connected to the connecting pipe 200 at a location further from the discharge mechanism 400 than locations where the plurality of deposition source units 100 are connected to the connecting pipe 200. Accordingly, since the second carrier gas is introduced from an inner side in the connecting pipe 200, the vaporized molecules of the material and the first carrier gas may be pushed up toward a discharge side, thereby being transferred in a good condition.

The bypass pipe 310 is connected to the gas supply source 400 through a mass flow controller 450b. A carrier gas output from the gas supply source 440 is supplied to the bypass pipe 310 while a flow of the carrier gas is adjusted by an opening degree of the mass flow controller 450b. The carrier gas introduced to the 3 deposition source units 100 corresponds to the first carrier gas, and the carrier gas introduced to the bypass pipe 310 corresponds to the second carrier gas. The first and second carrier gases may be an insert gas, such as a helium gas, a krypton gas, a xenon gas, or the like, aside from an argon gas.

A QCM (Quartz Crystal Microbalance: quartz crystal oscillator) 410 is provided near the substrate G. The QCM 410 is an example of a film thickness sensor, and detects a deposition rate (D/R) of film forming molecules discharge from the upper opening Op of the discharge mechanism 400. A principle of a QCM will now be described briefly.

When a material is adhered to a surface of a quartz crystal oscillator, and a size of a crystal oscillating body, modulus of elasticity, density, etc. are equivalently changed, an electric resonance frequency f represented by below equation is changed by piezoelectric property of an oscillator:

F=1/2t(√C/p), wherein t is a thickness of a crystal piece, C denotes an elastic constant, and p denotes density.

By using such a phenomenon, a very small amount of adhered matter is quantitatively measured according to a change of resonance frequency of the quartz crystal oscillator. A general term of the quartz crystal oscillator designed as such is QCM. As shown in the above equation, it may be assumed that the change of frequency is determined based on a thickness dimension when a change of elastic constant due to an adhered material, and an adhesion thickness are converted to crystal density. Thus, the change of frequency may be converted to a weight of the adhered matter.

By using such a principle, the QCM 410 outputs a frequency signal ft so as to detect a film thickness (deposition rate) adhered to the quartz crystal oscillator. A controller 700 is connected to the QCM 410, and thus receives the frequency signal ft output from the QCM 410 and converts the change of frequency into the weight of the adhered matter, thereby calculating a deposition rate.

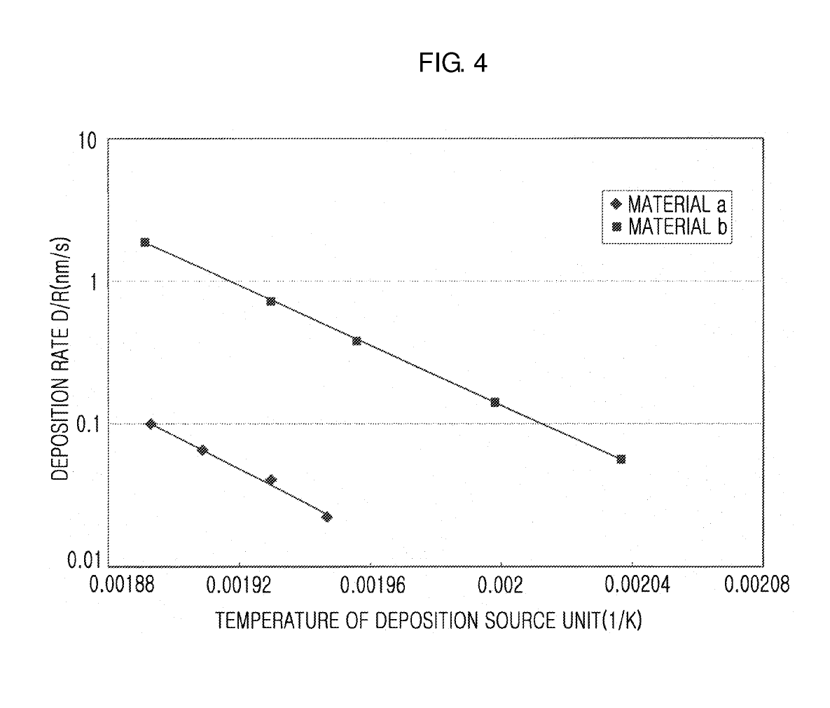

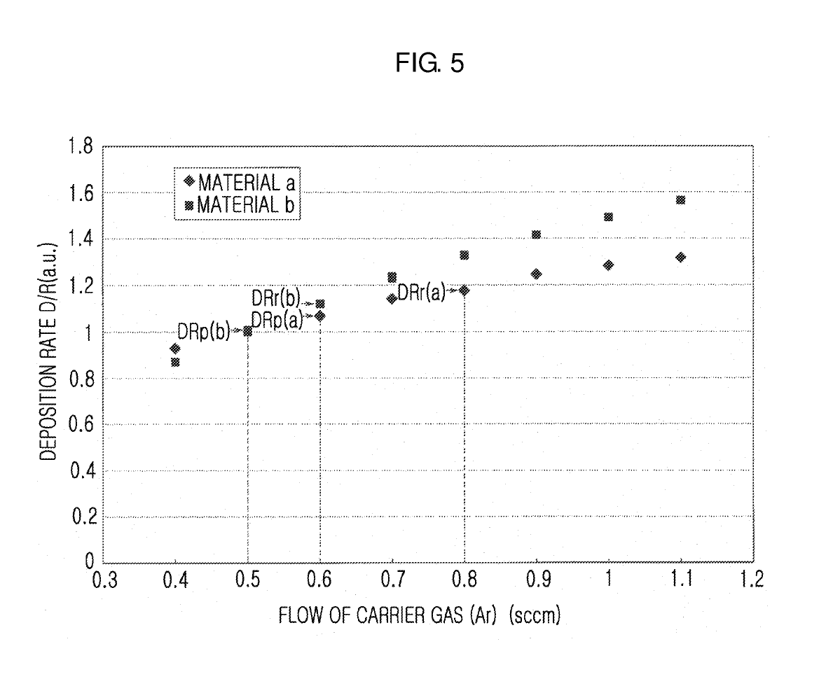

The controller 700 outputs a signal for controlling a deposition rate according to the calculated deposition rate, to a temperature controller 430 or the gas supply source 440. The controller 700 includes an ROM 700a, an RAM 700b, a CPU 700c, an input and output I/F 700d, and a bus 700e. The ROM 700a stores a basic program performed in the CPU 700c, a program activated during abnormality, etc. The RAM 700b accumulates various programs (a deposition rate checking process program or deposition rate controlling program, which will be described later) for controlling a film thickness, or data. For example, the RAM 700b pre-stores data indicating a correlation between temperature and a deposition rate of FIG. 4, or data indicating a correlation between a flow of a carrier gas and a deposition rate of FIG. 5. Here, the ROM 700a and the RAM 700b are examples of a storage device, and may be a storage device, such as EEPROM, an optical disk, an optical magnetic disk, or the like.

The CPU 700c obtains each voltage applied to the heater 130 of each deposition source unit 100 based on the frequency signal ft output from the QCM 410 by using the data or program stored in the ROM 700a or the RAM 700b, and transmits the obtained voltage to the temperature controller 430 as a control signal. The temperature controller 430 applies a required voltage to each heater 130 based on the control signal. As a result, the material container 110a is controlled to have a desired temperature, and thus an evaporation rate (vaporization rate) of the film-forming material is controlled.

Also, the CPU 700c obtains the flow of the first carrier gas introduced to each deposition source unit 100, and the flow of the second carrier gas introduced to the bypass pipe 310, from the frequency signal ft output from the QCM 410, and transmits the obtained flow of the first and second carrier gases to the gas supply source 440 and the mass flow controllers 450a and 450b, as a control signal. The gas supply source 440 supplies an argon gas based on the control signal, and the mass flow controllers 450a and 450b adjust an opening degree based on the control signal. Accordingly, a desired flow of the first carrier gas is introduced to each deposition source unit 100 at a desired timing, and at the same time, a desired flow of the second carrier gas is introduced to the bypass pipe 310 at a desired timing.

The bus 700e is a path for exchanging data between the ROM 700a, the RAM 700b, the CPU 700c, and the input and output I/F 700d. The input and output I/F 700d receives data from a keyboard or the like that is not shown, and outputs required data to a display, a speaker, or the like, which are not shown. Also, the input and output I/F 700d transmits and receives data to and from a device connected through a network. The deposition rate controlling process program and the evaporation rate checking process program, which will be described later, may be pre-stored in a storage medium, or obtained through a network.

[Control of Deposition Rate]

In order to form a film of good quality on a substrate by using the deposition apparatus 10, it is very important to precisely control a deposition rate. Accordingly, a method of heating a heater due to control of a temperature so as to control a deposition rate is generally used.

However, when the deposition rate is controlled by adjusting a temperature, responsiveness is bad since tens of seconds or more are taken until the heater is heated and the deposition source unit 100 actually reaches a desired temperature. Such bad responsiveness on the temperature control interrupts forming the film of good quality uniformly on the substrate G. Accordingly, the inventor invented that large change of a deposition rate is controlled by a temperature and small change of a deposition rate is controlled by a carrier gas.

The inventor obtained a relationship between a temperature (1/K) of the deposition source unit 100 and a deposition rate D/R (nm/s) via experiments. The inventor measured the deposition rate D/R when a temperature of each deposition source unit 100 is increased or decreased after, in the same deposition mechanism 600, the material container 110a of any one deposition source unit 100 stores an organic material ‘a’ and the material container 110a of another deposition source unit 100 stores an organic material ‘b’. Here, a flow of a carrier gas introduced to the deposition source unit 100 storing the material ‘a’ was 0.5 sccm, and a flow of a carrier gas introduced to the deposition source unit 100 storing the material ‘b’ was 1.0 sccm. As a result, the inventor obtained the data indicating the correlation between the temperature of the deposition source unit and the deposition rate as shown in FIG. 4, and the data were stored in the RAM 700b.

Next, the inventor obtained a relationship between a flow of an argon gas (first carrier gas) introduced to the deposition source unit 100 and a deposition rate D/R (a.u) via experiments. The inventor measured the deposition rate D/R when the argon gas introduced to each deposition source unit 100 is increased or decreased after, in the same deposition mechanism 600, the material container 110a of the first deposition source unit 100 stores the organic material ‘a’ and the material container 110a of the second deposition source unit 100 stores the organic material ‘b’. Here, a total flow of carrier gases respectively introduced to the deposition source unit 100 storing the material ‘a’ and the deposition source unit 100 storing the material ‘b’ was fixed to 1.5 sccm. Also, a temperature of the deposition source unit 100 storing the material ‘a’ was 248° C., and a temperature of the deposition source unit 100 storing the material ‘b’ was 244° C. As a result, the inventor obtained the data indicating the correlation between incerase of the carrier gas flow and the deposition rate as shown in FIG. 5, and the data were stored in the RAM 700b.

In the present embodiment, by using the data, the large change of the deposition rate is controlled by a temperature, and the small change of the deposition rate is controlled by a flow of a carrier gas. Detailed operations thereof will be described after describing a functional structure of the controller 700. Here, since FIGS. 4 and 5 show correlations about 2 types of film-forming materials stored in 2 deposition source units, film-forming materials whose evaporation rates are controllable are limited to the 2 types of film-forming materials stored in the 2 deposition source units. However, if data indicating correlations about 3 types of film-forming materials stored in 3 deposition source units are pre-obtained, evaporation rates of the respective film-forming materials in the 3 deposition source units may be controlled.

[Functional Structure of Controller]

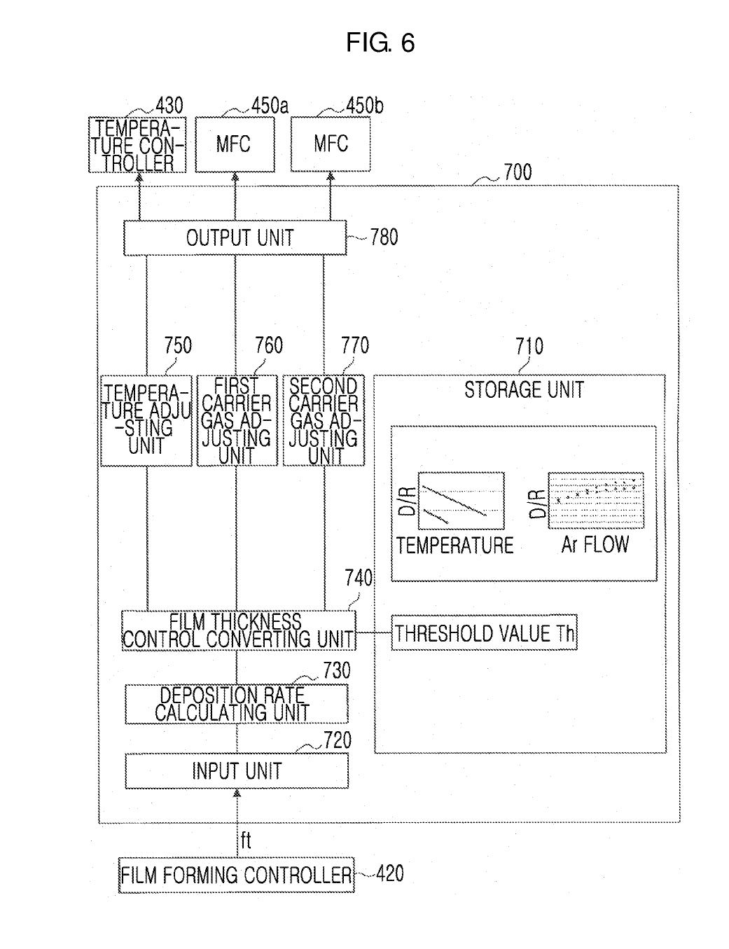

As shown in FIG. 6, the controller 700 has functions shown in respective block indicating a storage unit 710, an input unit 720, a deposition rate calculating unit 730, a film thickness control converting unit 740, a temperature adjusting unit 750, a first carrier gas adjusting unit 760, a second carrier gas adjusting unit 770, and an output unit 780. The storage unit 710 stores the data shown in FIG. 4, which indicates the correlation between the temperature of deposition source unit and the deposition rate, and the data shown in FIG. 5, which indicates the correlation between the flow of the carrier gas and the deposition rate. The storage unit 710 stores a predetermined threshold valve Th. The threshold value Th is used to determine whether a deposition rate is to be controlled by using a temperature or by using a gas flow. The storage unit 710 is actually a storage area, such as the ROM 700a, RAM 700b, or the like.

The input unit 720 inputs the frequency signal ft output from the QCM 410 at intervals of a predetermined time. The deposition rate calculating unit 730 calculates a deposition rate on the substrate G based on the frequency signal ft input by the input unit 720, and obtains a difference between the calculated deposition rate and a target deposition rate.

The film thickness control converting unit 740 controls the deposition rate due to temperature control when an absolute value of the deposition rate difference obtained by the deposition rate calculating unit 730 is more than the threshold value Th. When the deposition rate somewhat becomes a normal state due to the temperature control and thus the difference is less than or equal to the threshold vale Th, the film thickness control converting unit 740 converts a deposition rate controlling method so that the deposition rate is controlled by controlling the flow of the carrier gas.

The temperature adjusting unit 750, for example, adjusts a temperature of each deposition source unit so that the calculated deposition rate of each deposition source unit is close to the target deposition rate of each deposition source unit, by using the data indicating the relationship between the deposition rate and the temperature stored in the storage unit 710.

The first carrier gas adjusting unit 760, for example, adjusts the flow of the first carrier gas in each deposition source unit so that the calculated deposition rate of each deposition source unit is close to the target deposition rate of each deposition source unit, by using the data indicating the relationship between the deposition rate and the flow of the carrier gas stored in the storage unit 710.

The second carrier gas adjusting unit 770 adjusts the flow of the second carrier gas according to flow change of the first carrier gas introduced to the connecting pipe 200 via the adjustment of first carrier gas adjusting unit 760. In detail, when the flow of the first carrier gas is changed by the state of changing opening and closing of the plurality of valves 300, the second carrier gas adjusting unit 770 adjusts the flow of the second carrier gas according to a change amount of the first carrier gas. For example, the second carrier gas adjusting unit 770 adjusts the flow of the second carrier gas introduced to the bypass pipe 310 so that the total flow of the first and second carrier gases transferred through the connecting pipe 200 does not change.

When the deposition rate is controlled by the temperature, the output unit 780 outputs a control signal to the temperature controller 430 so that a voltage applied to the heater 130 is adjusted. When the deposition rate is controlled by the flow of the carrier gas, the output unit 780 outputs control signals to the mass flow controllers 450a and 450b and the gas supply source 440 so that the flow of the carrier gas is adjusted to a desired flow. Here, each function of the controller 700 described above is actually achieved by, for example, performing a program describing a processing order of realizing the functions by the CPU 700c.

[Operations of Controller]

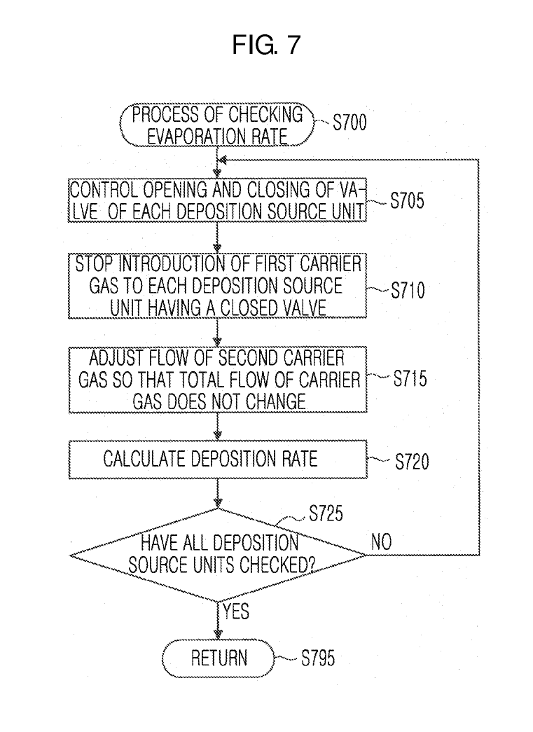

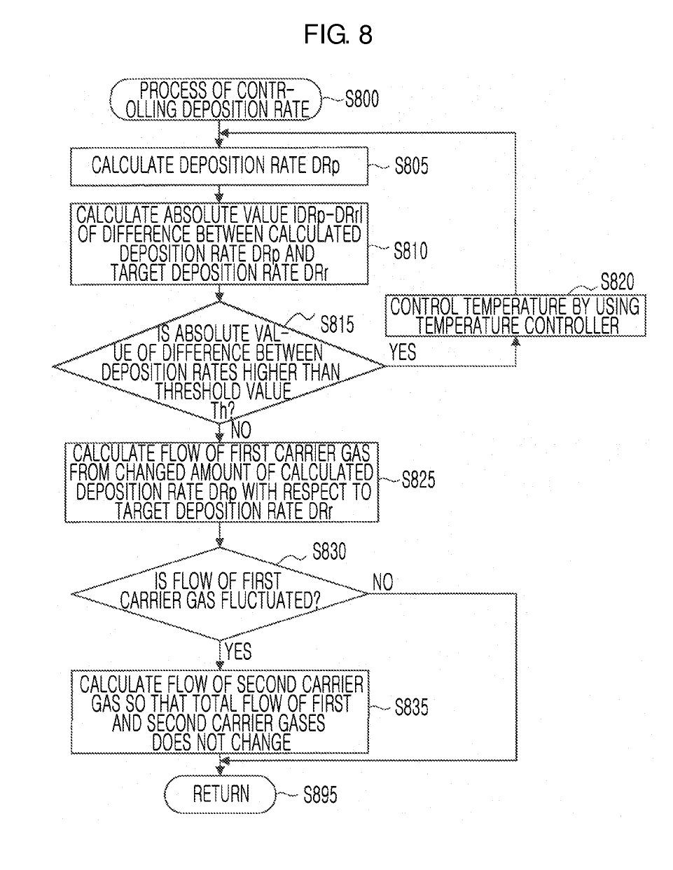

Next, operations of the controller 700 will now be described with reference to FIGS. 7 and 8. FIG. 7 is a flowchart showing a process of checking an evaporation rate of each material stored in each deposition source unit. FIG. 8 is a flowchart showing a process of controlling a deposition rate by controlling a flow of a carrier gas or a temperature of a deposition source unit.

The process of checking the evaporation rate shown in FIG. 7 is performed at a predetermined time, for example, whenever 2 or 3 sheets of substrate are processed or 1 sheet of substrate is processed, only twice a day of morning and evening, when a film-forming material in a deposition source unit is exchanged, or when a deposition source unit itself is exchanged. This is required to check whether an evaporation rate of each material is stabilized before forming a film on a product in the deposition apparatus 10, or to check change of an evaporation rate of each material after being used. Specifically, immediately after injecting a material, the material is unevenly dispersed, and thus a storage state of the material may be easily biased. In this case, it is difficult for the evaporation rate to be uniform. Accordingly, the process of checking the evaporation rate, in which an evaporation rate of each material is checked, is performed. Meanwhile, the process of controlling the deposition rate shown in FIG. 8 is performed at intervals of a predetermined time before and after a process and during a process.

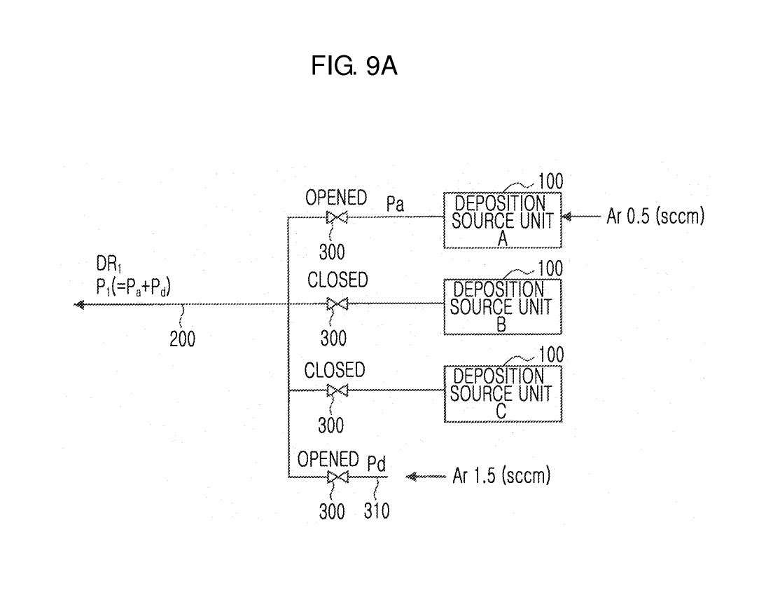

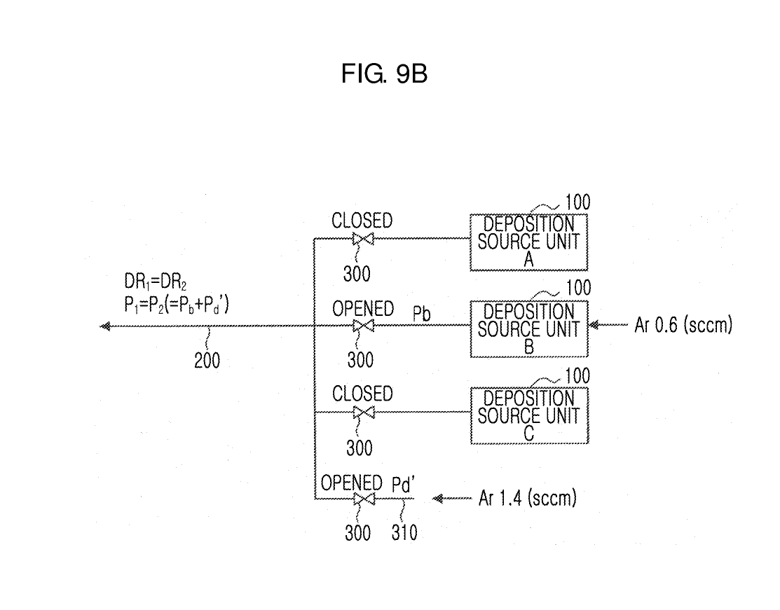

When the process of checking the evaporation rate is performed, it is assumed, herein, that one deposition source unit A from among the 3 deposition source units stores a material ‘a’, another deposition source unit B stores a material ‘b’, and another deposition source unit C does not store a material, as shown in FIG. 9A.

[Process of Checking Evaporation Rate]

First, the process of checking the evaporation rate shown in FIG. 7 will be described. According to the process of checking the evaporation rate, the process starts from step S700, and opening and closing of the valve 300 of each deposition source unit is controlled in step S705. For example, when the evaporation rates of the film-forming materials in the deposition source units 100 are checked one after another, first, in order to check the evaporation rate of the material ‘a’ stored in the deposition source unit A, the valves of the deposition source unit A and the bypass pipe 310 are opened, and the valves 300 of the deposition source units B and C are closed, as shown in FIG. 9A.

Next, step S710 is performed so as to stop introduction of the first carrier gas to each deposition source unit having a closed valve. In FIG. 9A, the first carrier gas of 0.5 sccm is introduced to the deposition source unit A, but is not introduced to the deposition source units B and C. Next, step S715 is performed to adjust the flow of the second carrier gas introduced from the bypass pipe 310 so that the total flow of the carrier gas introduced to the connecting pipe 200 is not changed. During co-deposition (during production process), when the total flow of the carrier gas is 2.0 sccm, the second carrier gas of 1.5 sccm is introduced to the bypass pipe 310, in FIG. 9A.

Then, step S720 is performed so that the deposition rate calculating unit 730 calculates the deposition rate from an output of the QCM 410. Here, the total flow 2.0 sccm of the carrier gas is equal to the flow during the co-deposition. Accordingly, internal pressure of the connecting pipe 200 is the same as pressure during the co-deposition. Accordingly, a detected evaporation rate of a single film-forming material is the same as an actual evaporation rate during the co-deposition. As a result, the actual evaporation rate of the material ‘a’ in the deposition source unit A during the co-deposition may be measured.

Next, step S725 is performed to determine whether the deposition rates of the materials in all deposition source units have been checked. Here, since the deposition rates of the materials in the deposition source units B and C are not checked, processes of steps S705 through S725 are repeated after returning to step S705.

In step S705, in order to check the evaporation rate of the material ‘b’ stored in the deposition source unit B, the valves 300 of the deposition source unit B and the bypass pipe 310 are opened, and the valves 300 of the deposition source units A and C are closed as shown in FIG. 9B. In that condition, step S710 is performed to introduce the first carrier gas of, for example, 0.6 sccm, to the deposition source unit B, and stop introduction of the first carrier gas to the deposition source units A and C, and thus the flow of the first carrier gas is changed. Accordingly, in step S715, the flow of the second carrier gas is adjusted to 1.4 sccm so that the total flow does not change

Accordingly, since the total flow of the carrier gas is the same as the flow during the co-deposition, the deposition rate calculated in step S720 is identical to the actual evaporation rate of the material ‘b’ during the co-deposition. The steps S705 through S725 described above are also performed on the deposition source unit C, thereby checking the evaporation rate of the single material in all deposition source units and then performing step S795 to end the present process.

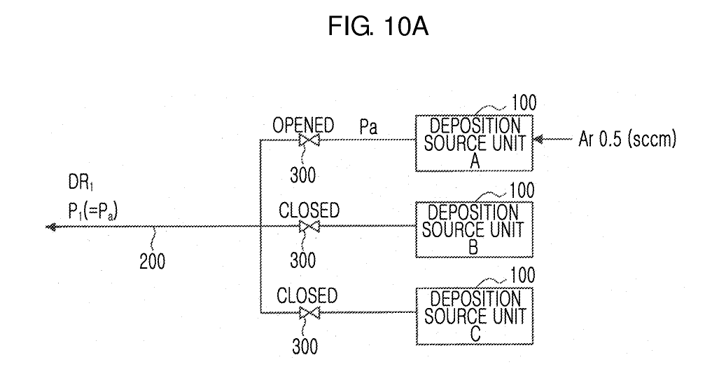

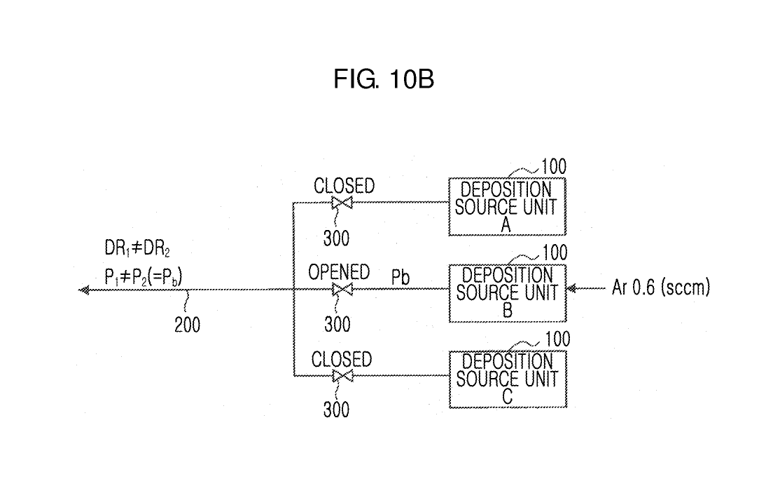

If a bypass pipe does not exist as shown in FIGS. 10A and 10B, the total flow of the carrier gas changes when the valves 300 of the deposition source units other than a deposition source unit to detect an evaporation rate of a material, are closed, and thus pressure inside a connecting pipe is changed. Thus, a detected evaporation rate of a single film-forming material differs from an actual evaporation rate during co-deposition.

However, according to the present embodiment, as described above, the bypass pipe 310 is provided and the second carrier gas is supplied through the bypass pipe 310, and thus the total flow of the carrier gas may be maintained constant. Accordingly, even if a QCM is not provided on all the deposition source unit, an actual evaporation rate of the material in each deposition source unit during co-deposition may be measured by adjusting the flow of the second carrier gas and opening and closing the valve 300.

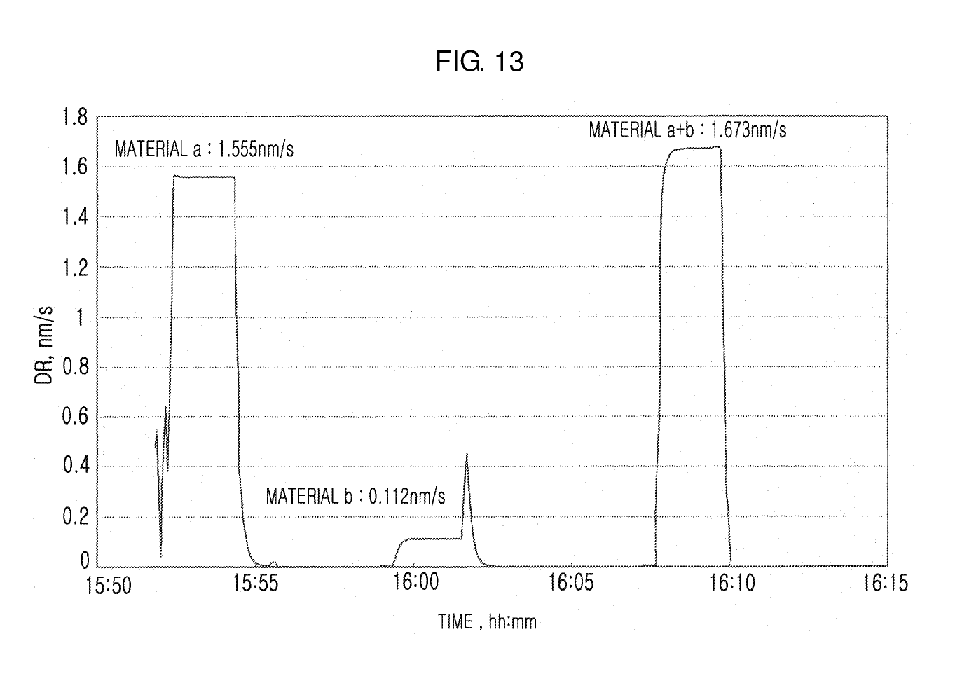

For example, according to measurement results of the QCM 410 shown in FIG. 13, an evaporation rate of a material ‘a’ was 1.555 nm/s when only the valve 300 of a deposition source unit A storing the material ‘a’ is opened. Similarly, an evaporation rate of a material ‘b’ was 0.112 nm/s when only the valve 300 of a deposition source unit storing the material ‘b’ is opened. Also, a deposition rate on a substrate was 1.673 nm/s, when all valves are opened and then a film is formed by mixing vaporized molecules of the materials ‘a+b’. Accordingly, it is checked that evaporation rate of a material in which the material ‘a’ and material ‘b’ are mixed at a predetermined mixture ratio, a sum of the evaporation rates of the respective materials measured by opening only the valve corresponding to a material which is to be measured, and the entire deposition rate measured by opening all valves are almost the same. Accordingly, the above-described process of checking the evaporation rate is performed, and the evaporation rate of each deposition source unit is controlled to a target rate, so that the deposition rate on the substrate is precisely controlled to be a target deposition rate during the process of controlling the deposition rate, which will now be described.

[Process of Controlling Deposition Rate]

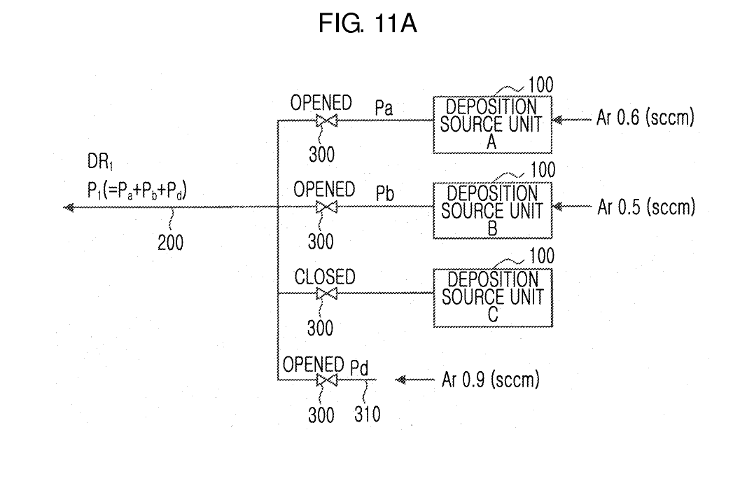

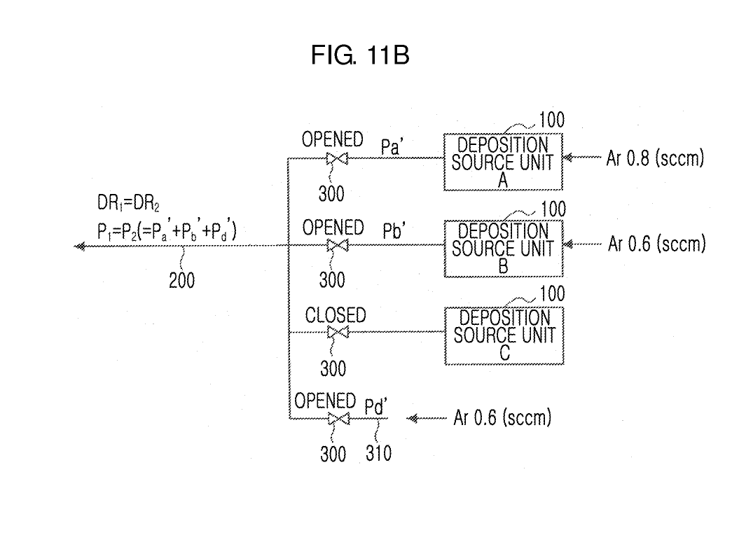

Next, the process of controlling the deposition rate shown in FIG. 8 will be described. As shown in FIG. 11A, at this time, the valves 300 of the deposition source unit A, the deposition source unit B, and the bypass pipe 310 are opened, and the valve 300 of the deposition source unit C is closed. Also, as a carrier gas, an argon gas of 0.6 sccm is introduced to the deposition source unit A, an argon gas of 0.5 sccm is introduced to the deposition source unit B, and an argon gas of 0.9 sccm is introduced to the bypass pipe 310. Accordingly, the total flow of the carrier gas is 2.0 sccm.

The process of controlling the deposition rate starts from step S800 of FIG. 8. When step S805 is performed, the deposition rate calculating unit 730 calculates a deposition rate DRp. In step S810, the deposition rate calculating unit 730 obtains an absolute value |DRp−DRr| of a difference between the calculated deposition rate DRp and a target deposition rate DRr.

Then, in step 815, the film thickness control converting unit 740 determines whether the absolute value of the difference (changed amount) of the deposition rates is higher than the threshold value Th. When the absolute value of the difference of the deposition rates is higher than the threshold value Th since an internal state of the deposition source unit is not stabilized, step S820 is performed so that the temperature adjusting unit 750 obtains an adjustment amount of a temperature required for the deposition rate at the present point of time to be close to the target deposition rate, based on the correlation between the deposition rate and the temperature shown in FIG. 4. The temperature adjusting unit 750 calculates a voltage applied to a heater, according to the obtained adjustment amount of temperature. The output unit 780 outputs to the temperature controller 430 a control signal directing to apply the calculated voltage to the heater 130 and then the process returns to step S805. Processes of steps S805 through S815 are repeated.

When a state inside the deposition source unit is stabilized, in step S815, the absolute value of the difference between the actual value and the target value of the deposition rate becomes less than or equal to the threshold value Th. In this case, step S825 is performed so that the first carrier gas adjusting unit 760 obtains an adjustment amount of the first carrier gas introduced to each deposition source unit, based on the correlation between the carrier gas and the temperature shown in FIG. 5. The adjustment amount of the first carrier gas is an amount required for the deposition rate at the present point of time to be close to the target deposition rate,

It may be predicted that a value obtained by dividing the deposition rate DRp calculated from the deposition rate calculating unit 730 by a predetermined mixture ratio of materials is equal to the present evaporation rate of each material. Thus, the first carrier gas adjusting unit 760 calculates values obtained by dividing the deposition rate DRp by the predetermined mixture ratio of materials, as the evaporation rate of the material ‘a’ and the evaporation rate of the material ‘b’. The first carrier gas adjusting unit 760 calculates differences between the calculated evaporation rates of the materials ‘a’ and ‘b’, and the target deposition rates of the materials ‘a’ and ‘b’ based on the data indicating the correlation between the gas flow and the deposition rate of FIG. 5, and calculates the flow of the first carrier gas introduced to the deposition source unit A storing the material ‘a’ and the flow of the first carrier gas introduced to the deposition source unit B storing the material ‘b’.

Now, it will be described that the flow of the first carrier gas introduced to each deposition source unit is calculated by using the correlation data shown in FIG. 5. When the calculated deposition rate DRp(a) of the material ‘a’ is about 1.1 a.u., and the target deposition rate DRr(a) of the material ‘a’ is about 1.2 a.u., the flow of the carrier gas corresponding to the difference between the present deposition rate and the target deposition rate is 0.2 sccm. Accordingly, the first carrier gas adjusting unit 760 generates a control signal for increasing the flow of the first carrier gas introduced to the deposition source unit storing the material ‘a’ by 0.2 sccm in step S725, and the output unit 780 outputs the control signal.

Similarly, when the calculated deposition rate DRp(b) of the material ‘b’ is about 1.0 a.u., and the target deposition rate DRr(b) of the material ‘b’ is about 1.1 a.u., the flow of the carrier gas corresponding to the difference between the present deposition rate and the target deposition rate is 0.1 sccm. Thus, the first carrier gas adjusting unit 760 generates a control signal for increasing the flow of the first carrier gas introduced to the deposition source unit storing the material ‘b’ by 0.1 sccm in step S825, and the output unit 780 outputs the control signal. Accordingly, as shown in FIG. 11B, the flow of the carrier gases respectively introduced to the deposition source units A and B are changed to 0.8 sccm and 0.6 sccm, and thus the evaporation rates of the film-forming materials ‘a’ and ‘b’ are close to target values. Accordingly, a film of good quality may be formed by precisely controlling the mixture ratio of each film-forming material contained in the film on the substrate.

Next, in step S830, the second carrier gas adjusting unit 770 determines whether the flow of the first carrier gas introduced to each deposition source unit has been changed. When the flow of the first carrier gas does not change, step S895 is immediately performed to end the present process. If the flow of the first carrier gas changes, step S835 is performed so that the second carrier gas adjusting unit 770 calculates the flow of the second carrier gas in which the total flow of the first and second carrier gases does not change, and step S895 is performed to end the present process.

For example, in the above example, the introducing amount of the first carrier gas changes from a state of introducing 1.1 sccm as shown in FIG. 11A to a state of introducing 1.4 sccm as shown in FIG. 11B. Accordingly, the second carrier gas adjusting unit 770 reduces the flow of the second carrier gas by an increased flow of the first carrier gas, i.e., to 0.6 sccm, so that the total flow 2.0 sccm of the first and second carrier gases does not change.

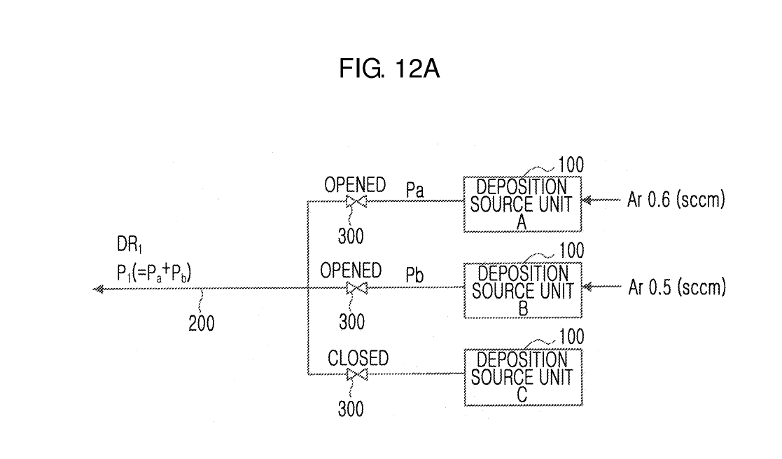

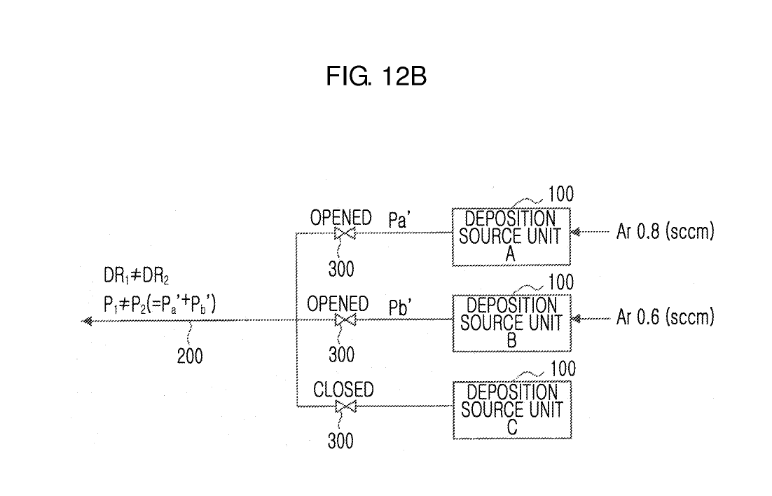

As shown in FIGS. 12A and 12B, in a state where the bypass pipe 310 is not provided, when precision of the mixture ratio of each film-forming material contained in the film on the substrate is controlled to be improved by adjusting the flow of the first carrier gas and drawing the evaporation rate of each of the film-forming materials ‘a’ and ‘b’ near to the target value, the pressure inside each deposition source unit changes (pressure Pa of the deposition source unit A of FIG. 12A≠pressure Pa′ of the deposition source unit A of FIG. 12B, and pressure Pb of the deposition source unit B 0 pressure Pb′ of the deposition source unit B), and thus pressure P₁ inside a connecting pipe before adjustment differs from pressure P₂ inside the connecting pipe after adjustment. As a result, a deposition rate DR₁ before adjustment and a deposition rate DR₂ after adjustment differ from each other, thereby generating unevenness of the film.

Meanwhile, in the present embodiment, the bypass pipe 310 is provided. From such a configuration, total flow of the first and second carrier gases may be maintained constant by adjusting the flow of the second carrier gas according to the adjustment of the flow of the first carrier gas. Accordingly, in the present embodiment, the pressure P₁ inside the connecting pipe before adjustment and the pressure P₂ inside the connecting pipe after adjustment may be maintained constant. As a result, the deposition rate DR₁ before adjustment and the deposition rate DR₂ after adjustment may be same, thereby maintaining uniformity of the film. Accordingly, performance of a product may be increased.

In other words, according to the present embodiment, the mixture ratio of the plurality of film-forming materials used to form the film is accurately controlled by adjusting the first carrier gas, thereby forming a film of good quality on the substrate while the pressure inside the transfer passage to the discharge mechanism is maintained constant by adjusting the second carrier gas, thereby constantly maintaining the deposition rate on the substrate.

In the above embodiments, operations of units are related to each other, and thus may be substituted by series of operations while considering the relation. Also, through such substitution, the embodiment of the deposition apparatus may become an embodiment of a deposition method.

In addition, by substituting the operations of the units by processes of the units, the embodiment of the deposition method may become an embodiment of a computer program for executing the deposition method in a computer, or an embodiment of a computer readable storage medium having the program stored therein.

While this invention has been particularly shown and described with reference to exemplary embodiments thereof, the present invention is not limited thereto. It will be understood by those skilled in the art that various changes in form and details may be made therein without departing from the spirit and scope of the invention as defined by the appended claims. It will be understood that those changes are also within the technical range of the present invention.

For example, in the deposition apparatus 10 according to the above embodiment, a process of forming an organic EL multi-layer film on the substrate G is performed by using an organic EL material having a powder shape (solid) as the film-forming material. However, a deposition apparatus according to the present invention may be used in, for example, MOCVD (Metal Organic Chemical Vapor Deposition), which decomposes a vaporized film-forming material on a target object heated up to 500 to 700° C. by mainly using a liquid organic metal as the film-forming material, so as to grow a thin film on the target object.

1. A deposition apparatus comprising:
a plurality of deposition sources, each of which includes a material container and a carrier gas introducing pipe, vaporizes a film-forming material stored in the material container, and transfers vaporized molecules of the film-forming material by using a first carrier gas introduced from the carrier gas introducing pipe;
a connecting pipe, which is connected to each of the plurality of deposition sources and transfers the vaporized molecules of the film-forming material transferred from each deposition source;
a bypass pipe, which is connected to the connecting pipe and directly introduces a second carrier gas to the connecting pipe; and
a processing container, which includes a built-in discharge mechanism connected to the connecting pipe, and forms a film on a target object by discharging, from the discharge mechanism, the vaporized molecules of the film-forming material transferred by using the first and second carrier gases.

2. The deposition apparatus of claim 1, further comprising:
a plurality of opening and closing mechanisms, which are each provided between the plurality of deposition sources and the connecting pipe and open or close transfer passages connecting the plurality of deposition sources and the connecting pipe; and
a controller, which adjusts a flow of the second carrier gas according to change of a flow of the first carrier gas introduced from the plurality of deposition sources to the connecting pipe due to the opening and closing of the transfer passage by the plurality of opening and closing mechanisms.

3. The deposition apparatus of claim 1, wherein the bypass pipe is connected to the connecting pipe, at a location further from the discharge mechanism than locations where the plurality of deposition sources are connected to the connecting pipe.

4. The deposition apparatus of claim 2, wherein the controller includes:
a storage unit, which shows a relationship between a deposition rate of each film-forming material and a flow of a carrier gas;
a deposition rate calculating unit, which calculates a deposition rate onto the target object based on an output signal from a film thickness sensor disposed inside the processing container;
a first carrier gas adjusting unit, which adjusts a flow of the first carrier gas in each deposition source so that the deposition rate calculated by the deposition rate calculating unit is close to a target deposition rate, by using the relationship between the deposition rate and the flow of the carrier gas shown in the storage unit; and
a second carrier gas adjusting unit, which adjusts a flow of the second carrier gas according to the change of the flow of the first carrier gas introduced to the connecting pipe according to the adjustment of the first carrier gas adjusting unit.

5. The deposition apparatus of claim 4, wherein the first carrier gas adjusting unit adjusts, if a difference between the deposition rate calculated by the deposition rate calculating unit and the target deposition rate of each deposition source is smaller than a predetermined threshold value, the flow of the first carrier gas in each deposition source so that the deposition rate becomes close to the target deposition rate of each deposition source.

6. The deposition apparatus of claim 4, wherein the second carrier gas adjusting unit adjusts the flow of the second carrier gas introduced to the bypass pipe so that a total flow of the first and second carrier gases transferred through the connecting pipe does not change.

7. The deposition apparatus of claim 4, further comprising a temperature adjusting unit which adjusts, if the difference between the deposition rate of each deposition source calculated by the deposition rate calculating unit and the target deposition rate of each deposition source is equal to or higher than the predetermined threshold value, a temperature of each deposition source so that the deposition rate becomes close to the target deposition rate of each deposition source.

8. The deposition apparatus of claim 1, wherein an organic EL film or an organic metal film is formed on the target object by using an organic EL film-forming material or an organic metal film-forming material as the film-forming material.

9. A deposition method comprising:
vaporizing, in each of a plurality of deposition sources each including a material container and a carrier gas introducing pipe, each film-forming material stored in a material container and transferring vaporized molecules of the film-forming material by using a first carrier gas introduced from the carrier gas introducing pipe;
transferring the vaporized molecules of the film-forming material transferred from each deposition source, to a connecting pipe connected to each of the plurality of deposition sources;
directly introducing a second carrier gas to the connecting pipe from a bypass pipe connected to the connecting pipe; and
discharging, from a discharge mechanism connected to the connecting pipe, the vaporized molecules of the film-forming material transferred by using the first and second carrier gases and forming a film on a target object inside a processing container.

10. The deposition method of claim 9, further comprising opening and closing transfer passages connecting the plurality of deposition sources and the connecting pipe, by using a plurality of opening and closing mechanisms respectively provided between the plurality of deposition sources and the connecting pipe,
wherein, in the directly introducing of the second carrier gas to the connecting pipe from the bypass pipe, the second carrier gas is introduced to the connecting pipe while adjusting a flow of the second carrier gas according to change of the flow of the first carrier gas introduced to the connecting pipe from the plurality of deposition sources due to opening and closing of the transfer passages by using the opening and closing mechanism.

11. A storage medium having stored therein a computer program for executing:
a process of vaporizing, in each of a plurality of deposition sources each including a material container and a carrier gas introducing pipe, each film-forming material stored in a material container and transferring vaporized molecules of the film-forming material by using a first carrier gas introduced from the carrier gas introducing pipe;
a process of transferring the vaporized molecules of the film-forming material transferred from each deposition source, to a connecting pipe connected to each of the plurality of deposition sources;
a process of directly introducing a second carrier gas to the connecting pipe from a bypass pipe connected to the connecting pipe; and
a process of transferring the vaporized molecules of the film-forming material to a discharge mechanism connected to the connecting pipe by using the first and second carrier gases, and forming a film on a target object inside a processing container by discharging the vaporized molecules of the film-forming material from a discharge mechanism.
